(19) United States
(12) Patent Application Publication
(10) Pub. No.: US 2024/0006853 A1
(43) Pub. Date: Jan. 4, 2024

(54) LASER DIODE AND METHOD FOR MANUFACTURING THE SAME

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/335,955

(22) Filed: Jun. 15, 2023

(30) Foreign Application Priority Data
Jun. 30, 2022 (CN) 202210772920.X

(51) Int. Cl. H01S 5/183; H01S 5/10; H01S 5/125; H01S 5/20

(52) U.S. Cl. CPC H01S 5/18377; H01S 5/1025; H01S 5/125; H01S 5/2081; H01S 5/18386; H01S 2304/12

(57) ABSTRACT

A structure includes a base; a first mask layer disposed on the base, where the first mask layer has a first channel exposing the base, the first channel comprises a first open end and a second open end, the second open end is close to a surface of the base, the first open end is away from the surface of the base, and an area of an orthographic projection of the first open end in a plane where the base is located is smaller than an area of an orthographic projection of the first channel in the plane; and a second mask layer disposed on the first mask layer, where the second mask layer has a second channel exposing the first mask layer, and the second channel is connected to the first channel.

### CROSS REFERENCE TO RELATED APPLICATIONS

This application claims priority to Chinese Patent Application No. 202210772920.X, filed on Jun. 30, 2022, the entire content of which is incorporated herein by reference.

### TECHNICAL FIELD

The present disclosure relates to the field of semiconductors, in particular to a structure, a method for manufacturing a structure, a laser diode, and a method for manufacturing a laser diode.

### BACKGROUND

Gallium nitride (GaN) is the third generation of new semiconductor material after first and second generation semiconductor materials such as Si, GaAs and so on. GaN has many advantages as a wide band semiconductor material, such as high saturation drift speed, large breakdown voltage, excellent carrier transport performance and the ability to form AlGaN, InGaN ternary alloys and AlInGaN quaternary alloys, such that GaN-based PN junctions are easily manufactured. In view of this, in recent years, GaN-based materials and semiconductor devices have received extensive and in-depth research, metal-organic chemical vapor deposition (MOCVD) technology to grow GaN-based materials is becoming increasingly mature. In the field of semiconductor device research, significant achievements and significant development have been made in optoelectronic devices such as GaN-based light-emitting devices (LEDs) and laser devices (LDs), as well as microelectronic devices such as GaN-based high electron mobility transistors (HEMTs).

With the application of GaN-based materials in power devices or displays, the demand for dislocation density of GaN-based materials in the terminal products has further increased, and the dislocation surface density of GaN-based materials epitaxially grown on the mainstream GaN-based epitaxial substrate (Al₂O₃ substrate) by using the mainstream MOCVD epitaxial device in traditional mode is about 1˜3E8/cm³. In order to manufacture GaN-based power devices that are more resistant to high voltage and GaN-based LEDs with longer wavelength bands, the dislocation density of GaN-based materials needs to be further reduced.

In view of this, it is necessary to provide a new structure and a method for manufacturing the same, as well as a laser diode and a method for manufacturing the same to meet the above needs.

### SUMMARY

The present disclosure aims to provide a structure, a method for manufacturing a structure, a laser diode, and a method for manufacturing a laser diode, to reduce the dislocation density of the GaN-based material.

According to a first aspect of the present disclosure, there is provided a structure, structure, including: a base; a first mask layer on the base, where the first mask layer has a first channel exposing the base, the first channel includes a first open end and a second open end, the second open end is close to a surface of the base, the first open end is away from the surface of the base, and an area of an orthographic projection of the first open end in a plane where the base is located is smaller than an area of an orthographic projection of the first channel in the plane; and a second mask layer on the first mask layer, where the second mask layer has a second channel exposing the first mask layer, and the second channel is connected to the first channel.

In an embodiment, the first mask layer is a multilayer structure, the first mask layer includes a first sub-layer close to the base and a second sub-layer away from the base, and a material of the second sub-layer is different from that of the second mask layer.

In an embodiment the first mask layer and the second mask layer are both single-layer structures, and a material of the first mask layer is different from that of the second mask layer.

In an embodiment, an area of a cross section of the second channel is larger than an area of the first open end of the first channel.

In an embodiment, the orthographic projection of the first open end in the plane where the base is located does not overlap at least partially with the second open end.

In an embodiment, the first channel is an inclined columnar channel.

In an embodiment, in an extending direction from the second open end towards the first open end, a cross sectional area of the first channel firstly increases and then decreases; or in an extending direction from the second open end towards the first open end, a cross sectional area of the first channel gradually decreases; or in an extending direction from the second open end towards the first open end, a cross sectional area of the first channel is constant.

In an embodiment, a line connecting centres of cross sections of the first channel in an extending direction from the second open end towards the first open end is a straight line, a polyline, or a curve.

According to a second aspect of the present disclosure, there is provided a laser diode, including: the structure according to the first aspect; a first epitaxial layer including a first epitaxial sub-layer and a second epitaxial sub-layer, where the first epitaxial sub-layer is epitaxially grown from the base to fully fill the first channel, and the second epitaxial sub-layer is epitaxially grown, from the first epitaxial sub-layer located at the first open end, in the second channel; an active layer on the second epitaxial sub-layer, where the active layer is located within the second channel; a second epitaxial layer on the active layer, where a light-emitting structure is formed by the second epitaxial sub-layer, the active layer and the second epitaxial layer; and a first Bragg reflector and a second Bragg reflector, which are on opposite sides of the light-emitting structure respectively, so as to allow light emitted from the light-emitting structure to exit from either of the opposite sides.

In an embodiment, the second mask layer on the opposite sides of the light-emitting structure includes a plurality of protruding walls spaced in a direction perpendicular to an end face of the light-emitting structure to correspondingly form the first Bragg reflector and the second Bragg reflector, so as to allow the light emitted from the light-emitting structure to exit from either of the opposite sides in the direction perpendicular to the end face of the light-emitting structure.

In an embodiment, the first Bragg reflector and the second Bragg reflector both include a plurality of repeating units, and each of the plurality of repeating units includes a protruding wall and an air gap adjacent a side of the protruding wall; when a number of repeating units of the first Bragg reflector is smaller than that of the second Bragg reflector, the first Bragg reflector corresponds to a light-emitting surface of the light-emitting structure; when the number of repeating units of the first Bragg reflector is larger than that of the second Bragg reflector, the second Bragg reflector corresponds to the light-emitting surface of the light-emitting structure.

In an embodiment, the plurality of protruding walls respectively have the same width, and air gaps between the plurality of protruding walls respectively have the same width.

In an embodiment, the first mask layer includes a fifth sub-layer and a sixth sub-layer arranged alternately to form the second Bragg reflector, and the first Bragg reflector is on the light-emitting structure and on the second mask layer, or on the light-emitting structure within the second channel.

According to a third aspect of the present disclosure, there is provided a method for manufacturing a structure, including: providing a base; forming a first mask layer on the base; forming a first channel within the first mask layer that exposes the base, where the first channel includes a first open end and a second open end, the second open end is close to a surface of the base, the first open end is away from the surface of the base, and an area of an orthographic projection of the first open end in a plane where the base is located is smaller than an area of an orthographic projection of the first channel in the plane; forming a second mask layer on the first mask layer; and forming a second channel within the second mask layer that exposes the first mask layer, where the second channel is connected to the first channel.

In an embodiment, the first mask layer is a multilayer structure, the first mask layer includes a first sub-layer close to the base and a second sub-layer away from the base, and a material of the second sub-layer is different from that of the second mask layer.

In an embodiment, the first mask layer and the second mask layer are both single-layer structures, and a material of the first mask layer is different from that of the second mask layer.

According to a fourth aspect of the present disclosure, there is provided a method for manufacturing a laser diode, including: providing the structure according to claim 1; forming a first epitaxial layer, an active layer and a second epitaxial layer sequentially by performing an epitaxial growth process on the base with the first mask layer and the second mask layer as masks, where the first epitaxial layer includes a first epitaxial sub-layer and a second epitaxial sub-layer, the first epitaxial sub-layer is epitaxially grown from the base to fully fill the first channel, the second epitaxial sub-layer is epitaxially grown, from the first epitaxial sub-layer located at the first open end, in the second channel, the active layer is located within the second channel, and a light-emitting structure is formed by the second epitaxial sub-layer, the active layer and the second epitaxial layer; and forming a first Bragg reflector and a second Bragg reflector disposed on opposite sides of the light-emitting structure respectively, so as to allow light emitted from the light-emitting structure to exit from either of the opposite sides.

In an embodiment, forming the first Bragg reflector and the second Bragg reflector includes: etching the second mask layer on the opposite sides of the light-emitting structure to form a plurality of protruding walls spaced in a direction perpendicular to an end face of the light-emitting structure to correspondingly form the first Bragg reflector and the second Bragg reflector, so as to allow the light emitted from the light-emitting structure to exit from either of the opposite sides in the direction perpendicular to the end face of the light-emitting structure.

In an embodiment, the plurality of protruding walls respectively have the same width, and air gaps between the plurality of protruding walls respectively have the same width; the first Bragg reflector and the second Bragg reflector both include a plurality of repeating units, and each of the plurality of repeating units includes a protruding wall and an air gap adjacent a side of the protruding wall; when a number of repeating units of the first Bragg reflector is smaller than that of the second Bragg reflector, the first Bragg reflector corresponds to a light-emitting surface of the light-emitting structure; when the number of repeating units of the first Bragg reflector is larger than that of the second Bragg reflector, the second Bragg reflector corresponds to the light-emitting surface of the light-emitting structure.

In an embodiment, the base is a single-layer structure, the first epitaxial layer is formed by performing a homogeneous epitaxial growth process or a heterogeneous epitaxial growth process on the base; or the base includes a semiconductor substrate and a transition layer disposed on the semiconductor substrate, and the first epitaxial layer is formed by performing a homogeneous epitaxial growth process or a heterogeneous epitaxial growth process on the transition layer.

### BRIEF DESCRIPTION OF DRAWINGS

FIG. 1 is a schematic diagram illustrating a section of a structure according to a first embodiment of the present disclosure.

FIG. 2 is a flowchart illustrating a method for manufacturing the structure of FIG. 1.

FIG. 3 is a schematic diagram illustrating an intermediate structure corresponding to the process in FIG. 2.

FIG. 4 is a schematic diagram illustrating a section of a structure according to a second embodiment of the present disclosure.

FIG. 5 is a schematic diagram illustrating a section of a structure according to a third embodiment of the present disclosure.

FIG. 6 is a schematic diagram illustrating a section of a structure according to a fourth embodiment of the present disclosure.

FIG. 7 is a schematic diagram illustrating a section of a structure according to a fifth embodiment of the present disclosure.

FIG. 8 is a schematic diagram illustrating a section of a structure according to a sixth embodiment of the present disclosure.

FIG. 9(a) and FIG. 9(b) are schematic diagrams illustrating sections of two laser diodes according to a seventh embodiment of the present disclosure, respectively.

FIG. 10 is a flowchart illustrating a method for manufacturing a laser diode according to a seventh embodiment of the present disclosure.

FIG. 11 is a schematic diagram illustrating a section of a laser diode according to an eighth embodiment of the present disclosure.

FIG. 12 is a schematic diagram illustrating a section of a laser diode according to a ninth embodiment of the present disclosure.

For the convenience of understanding of the present disclosure, all reference numerals appearing in the present disclosure are listed below: structure 1, 2, 3, 4, 5, 6; base 10; semiconductor substrate 100; transition layer 101; first mask layer 11; first channel 110; first open end 110a; second open end 110b; inclined columnar channel 111; first sidewall 11a; second sidewall 11b; first angle α; second angle β; second mask layer 12; second channel 120; first sub-layer 112; second sub-layer 113; first epitaxial layer 13; first epitaxial sub-layer 131; second epitaxial sub-layer 132; active layer 14; second epitaxial layer 15; light-emitting structure 16; first Bragg reflector 121; second Bragg reflector 122; third sub-layer 114; fourth sub-layer 115; fifth sub-layer 116; sixth sub-layer 117; protruding wall 120a; air gap 120b; laser diodes 7, 8, 9.

### DETAILED DESCRIPTION

In order to make the above purposes, features, and advantages of present disclosure more obvious and understandable, embodiments of the present disclosure will be explained in detail below in conjunction with the accompanying drawings.

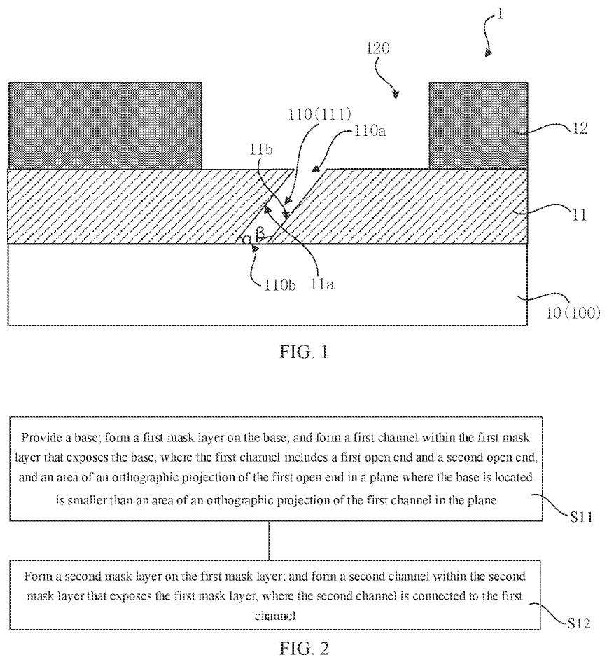

FIG. 1 is a schematic diagram illustrating a section of a structure according to a first embodiment of the present disclosure.

Referring to FIG. 1, the structure 1 includes:
a base 10;
a first mask layer 11 disposed on the base 10, where the first mask layer 11 has a first channel 110 exposing the base 10, the first channel 110 includes a first open end 110a and a second open end 110b, and an area of an orthographic projection of the first open end 110a in a plane where the base 10 is located is smaller than an area of an orthographic projection of the first channel 110 in the plane; and
a second mask layer 12 disposed on the first mask layer 11, where the second mask layer 12 has a second channel 120 exposing the first mask layer 11, and the second channel 120 is connected to the first channel 110.

In this embodiment, the base 10 is a multilayer structure, and the base 10 includes, for example, a semiconductor substrate 100 and a nucleation layer (not shown) disposed on the semiconductor substrate 100. A material of the semiconductor substrate 100 may include at least one of sapphire, silicon carbide, or monocrystalline silicon, and a material of the nucleation layer may include AlN.

In other embodiments, the base 10 may be a single-layer structure, for example, the base 10 is a semiconductor substrate 100. The material of the semiconductor substrate 100 may include silicon carbide, gallium nitride, etc.

In this embodiment, the first mask layer 11 and the second mask layer 12 are both single-layer structures. Materials of the first mask layer 11 and the second mask layer 12 are different and may be silicon dioxide and silicon nitride, respectively.

In this embodiment, there is one first channel 110, and the first channel 110 is an inclined columnar channel 111, and a longitudinal section of the inclined columnar channel 111 is an inclined parallelogram, where the longitudinal section refers to a section taken along a direction perpendicular to a plane where the base 10 is located. A cross section of the inclined columnar channel 111 is rectangular, where the cross section refers to a section taken along a direction parallel to a plane where the base 10 is located.

The first mask layer 11 includes a first sidewall 11a and a second sidewall 11b opposite to the first sidewall 11a. The first sidewall 11a is at a first angle α to the base 10 exposed by the inclined columnar channel 111, and the first angle α is an acute angle. The second sidewall 11b is at a second angle β to the base 10 exposed by the inclined columnar channel 111, and the second angle β is an obtuse angle. The first angle α is equal to a complementary angle of the second angle β.

The second open end 110b of the inclined columnar channel 111 is close to a surface of the base 10, the first open end 110a is away from the surface of the base 10, and the orthographic projection of the first open end 110a in the plane where the base 10 is located does not overlap at all with the second open end 110b, with the advantage that when the dislocation of the material epitaxially grown within the inclined columnar channel 111 is along a thickness direction of the first mask layer 11 or have an angle to the thickness direction, the smaller the angle between the side wall of the inclined columnar channel 111 and the direction parallel to the plane where the base 10 is located is, the larger an area of the side wall that terminates the dislocation extension is, and thus the better the termination effect is. For example, when the epitaxially grown material is GaN, the dislocation of the GaN material is mainly a threading dislocation with crystal orientation, i.e., a dislocation extending along the thickness direction of the first mask layer 11, the smaller the first angle α between the first sidewall 11a and the base 10 exposed by the inclined columnar channel 111 is, the larger the area of the first sidewall 11a that can terminate the dislocation extension is, and thus the better the termination effect is, thereby, the lower the dislocation density of the GaN material epitaxially grown within the second channel 120 is.

In other embodiments, the orthographic projection of the first open end 110a in the plane where the base 10 is located does not overlap at least partially with the second open end 110b.

In this embodiment, an area of a cross section of the second channel 120 is larger than an area of the first open end 110a of the first channel 110. In other embodiments, the area of the cross section of the second channel 120 may be less than or equal to the area of the first open end 110a of the first channel 110.

In other embodiments, the first channel 110 and the second channel 120 may be plural in number, and one second channel 120 may be connected to two or more first channels 110. The shape of the cross section of the second channel 120 and the shape of the cross section of the first channel 110 may be the same or different. The cross section of the second channel 120 and/or the first channel 110 may be triangular, hexagonal, circular, and other shapes.

At least two of the plurality of second channels 120 may have different cross sectional areas, or at least two pairs of adjacent second channels 120 of the plurality of second channels 120 may have different spacing distances.

For three second channels 120 in the same group, the cross sectional areas of the three second channels 120 may be different from each other, and two pairs of adjacent second channels 120 may have different spacing distances.

The size and spacing distance settings for the second channels 120 may enrich the quality or properties of the epitaxial material within the second channels 120.

In this embodiment, the structure 1 is a new epitaxial substrate structure.

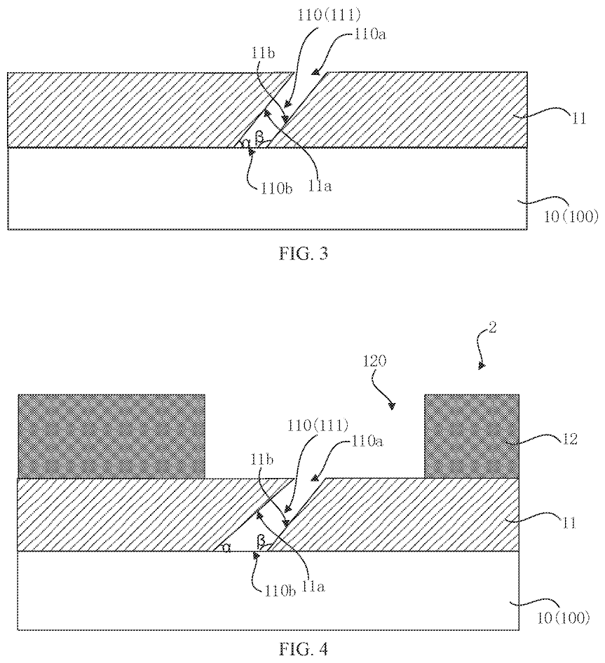

The first embodiment of the present disclosure also provides a method for manufacturing the structure in FIG. 1. FIG. 2 is a flowchart illustrating the method; and FIG. 3 is a schematic diagram illustrating an intermediate structure corresponding to the process in FIG. 2.

Referring to step S11 in FIG. 2 and FIG. 3, a base 10 is provided; a first mask layer 11 is formed on the base 10; a first channel 110 exposing the base 10 is formed within the first mask layer 11, where the first channel 110 includes a first open end 110a and a second open end 110b, and an area of an orthographic projection of the first open end 110a in a plane where the base 10 is located is smaller than an area of an orthographic projection of the first channel 110 in the plane.

In this embodiment, the base 10 is a multilayer structure, and the base 10 includes, for example, a semiconductor substrate 100 and a nucleation layer (not shown) disposed on the semiconductor substrate 100. The material of the semiconductor substrate 100 may include at least one of sapphire, silicon carbide, or monocrystalline silicon, and the material of the nucleation layer may include AlN.

In other embodiments, the base 10 may be a single-layer structure, for example, the base 10 is a semiconductor substrate 100. the material of the semiconductor substrate 100 may include silicon carbide.

The material of the first mask layer 11 may include one of silicon dioxide and silicon nitride, correspondingly, the first mask layer 11 may be formed by physical vapor deposition or chemical vapor deposition. In this embodiment, the first mask layer 11 is a single-layer structure. The single-layer structure can be formed by a single process.

In this embodiment, one first channel 110 is formed, and the first channel 110 is an inclined columnar channel 111. the inclined columnar channel 111 can be achieved by controlling the type and the flow rate of etching gas during dry etching, or controlling the plasma direction.

Referring to step S12 in FIG. 2, FIG. 3 and FIG. 1, a second mask layer 12 is formed on the first mask layer 11; a second channel 120 exposing the first mask layer 11 is formed within the second mask layer 12, and the second channel 120 is connected to the first channel 110.

The material of the second mask layer 12 may be one, different from the material of the first mask layer 11, of silicon dioxide and silicon nitride, correspondingly, the second mask layer 12 may be formed by physical vapor deposition method or chemical vapor deposition method. In this embodiment, the second mask layer 12 is a single-layer structure, and the single-layer structure can be formed by a single process. The material of the second mask layer 12 is different from that of the first mask layer 11, and the etching gas for etching the second channel 120 can be selected with a large etching selection ratio between the second mask layer 12 and the first mask layer 11, so as to detect the etching end by using the first mask layer 11.

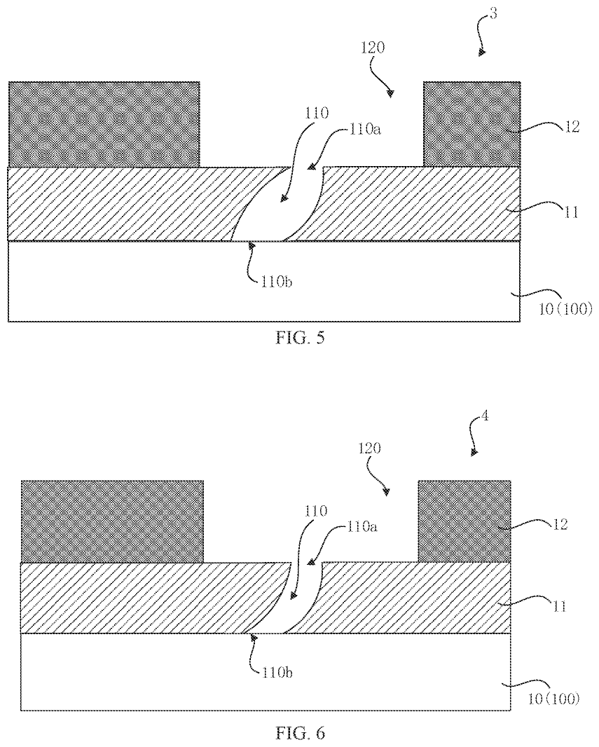

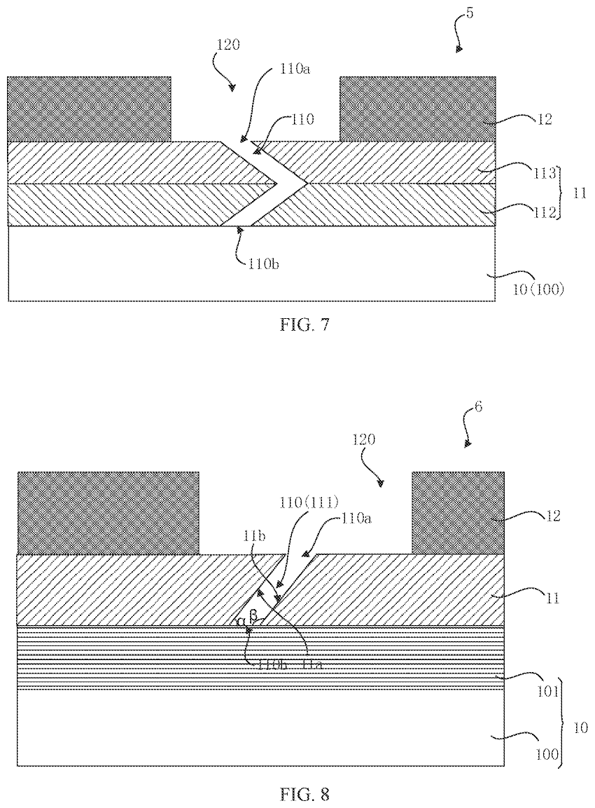

FIG. 4 is a schematic diagram illustrating a section of a structure according to a second embodiment of the present disclosure.

Referring to FIG. 4, the structure 2 and a method for manufacturing the same of the second embodiment differ from the structure 1 and the method for manufacturing the same of the first embodiment in that, in the second embodiment, the first angle α is less than the complementary angle of the second angle β in the inclined columnar channel 111.

By decreasing the first angle α, the area of the first sidewall 11a, which terminates the dislocation extension, can be increased, thus the dislocation termination effect in the GaN material epitaxially grown in the first channel 110 is better, thereby, the dislocation density of the GaN material epitaxially grown in the second channel 120 is lower.

In addition to the above difference, other parts of the structure 2 and process steps of manufacturing the structure 2 in the second embodiment can be referred to the corresponding parts of the structure 1 and the process steps in the first embodiment.

FIG. 5 is a schematic diagram illustrating a section of a structure according to a third embodiment of the present disclosure.

Referring to FIG. 5, the structure 3 and a method for manufacturing the same of the third embodiment differ from the structures 1 and 2, and the methods for manufacturing the structures 1 and 2 of the first and second embodiments only in that: in an extending direction from the second open end 110b towards the first open end 110a, a cross sectional area of the first channel 110 firstly increases and then decreases.

The cross sectional area of the first channel 110 is an area of a cross section taken along the direction parallel to the plane where the base 10 is located.

In addition to the above difference, other parts of the structure 3 and process steps of manufacturing the structure 3 in the third embodiment can be referred to the corresponding parts of the structures 1 and 2 and the process steps in the first and second embodiments.

FIG. 6 is a schematic diagram illustrating a section of a structure according to a fourth embodiment of the present disclosure.

Referring to FIG. 6, the structure 4 and a method for manufacturing the same of the fourth embodiment differ from the structures 1, 2, 3 and the methods for manufacturing the structures 1, 2, 3 of the first, second and third embodiments only in that: in an extending direction from the second open end 110b towards the first open end 110a, a cross sectional area of the first channel 110 is constant, and a line connecting centres of cross sections of the first channel 110 is a curve.

In other embodiments, in an extending direction from the second open end 110b towards the first open end 110a, a cross sectional area of the first channel 110 may firstly increase and then decrease, or gradually decrease; the cross section of the first channel 110 is a figure having a symmetrical centre, and a line connecting centres of cross sections of the first channel 110 in an extending direction from the second open end 110b towards the first open end 110a is a straight line.

In addition to the above difference, other parts of the structure 4 and process steps of manufacturing the structure 4 in the fourth embodiment can be referred to the corresponding parts of the structures 1, 2 and 3 and the process steps in the first, second and third embodiments.

FIG. 7 is a schematic diagram illustrating a section of a structure according to a fifth embodiment of the present disclosure.

Referring to FIG. 7, the structure 5 and a method for manufacturing the same of the fifth embodiment differ from the structures 1, 2, 3 and 4, and the methods for manufacturing the structures 1, 2, 3 and 4 of the first to fourth embodiments only in that: a line connecting centres of cross sections of the first channel 110 in an extending direction from the second open end 110b towards the first open end 110a is a polyline. In other words, the first channel 110 rises in a curved shape in the extending direction from the second open end 110b towards the first open end 110a.

In this embodiment, the first mask layer 11 may be a multilayer structure, the multilayer structure includes a first sub-layer 112 close to the base 10 and a second sub-layer 113 away from the base 10, a material of the first sub-layer 112 is different from a material of the second sub-layer 113, and a material of the second sub-layer 113 is different from a material of the second mask layer 12. The first sub-layer 112 and the second sub-layer 113 may be formed by using two processes. The materials of the first sub-layer 112 and the second sub-layer 113 are different to facilitate forming different sections of the first channel 110.

In other embodiments, the first channel 110 may rise in a twisted shape in the extending direction from the second open end 110b towards the first open end 110a. Correspondingly, the multilayer structure of the first mask layer 11 may be three or more layers, and materials of the layers are different from each other, to form different segments of the first channel 110.

In addition to the above difference, other parts of the structure 5 and process steps of manufacturing the structure 5 in the fifth embodiment can be referred to the corresponding parts of the structures 1, 2, 3 and 4 and the process steps in the first to fourth embodiments.

FIG. 8 is a schematic diagram illustrating a section of a structure according to a sixth embodiment of the present disclosure.

Referring to FIG. 8, the structure 6 and a method for manufacturing the same of the sixth embodiment differ from the structures 1, 2, 3, 4 and 5, and the methods for manufacturing the structures 1, 2, 3, 4 and 5 of the first to fifth embodiments only in that: the base 10 includes a semiconductor substrate 100 and a transition layer 101 disposed on the semiconductor substrate 100.

A material of the transition layer 101 and a material of the first epitaxial layer 13 may be the same or different.

The material of the transition layer 101 may include, for example, GaN. Compared to an example of epitaxially growing the GaN material directly on the sapphire or monocrystalline silicon semiconductor substrate 100 without the transition layer 101, this embodiment further reduces the dislocation density of the GaN material within the second channel 120.

In addition to the above difference, other parts of the structure 6 and process steps of manufacturing the structure 6 in the sixth embodiment can be referred to the corresponding parts of the structures 1, 2, 3, 4 and 5 and the process steps in the first to fifth embodiments.

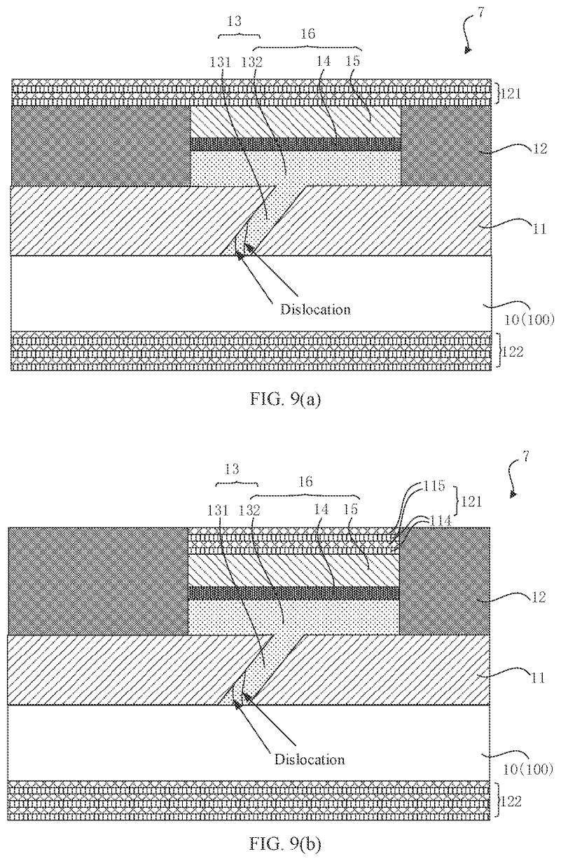

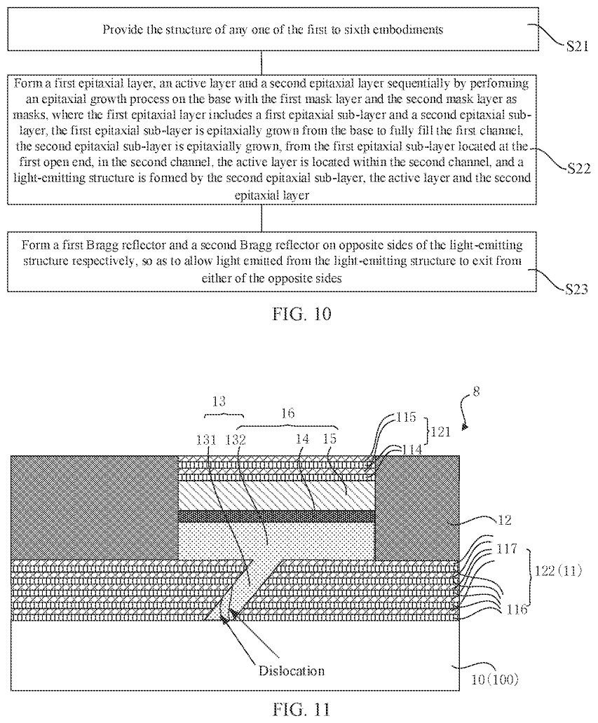

FIG. 9(a) and FIG. 9(b) are schematic diagrams illustrating sections of two laser diodes according to a seventh embodiment of the present disclosure, respectively.

Referring to FIG. 9(a) and FIG. 9(b), the laser diode 7 of the seventh embodiment includes:
the structures 1, 2, 3, 4, 5, and 6 of any of the first to sixth embodiments;
a first epitaxial layer 13 including a first epitaxial sub-layer 131 and a second epitaxial sub-layer 132, where the first epitaxial sub-layer 131 is epitaxially grown from the base 10 to fully fill the first channel 110, and the second epitaxial sub-layer 132 is epitaxially grown, from the first epitaxial sub-layer 131 located at the first open end 110a, in the second channel 120;
an active layer 14 disposed on the second epitaxial sub-layer 132, where the active layer 14 is located within the second channel 120;
a second epitaxial layer 15 disposed on the active layer 14, where a light-emitting structure 16 is formed by the second epitaxial sub-layer 132, the active layer 14 and the second epitaxial layer 15; and
a first Bragg reflector 121 and a second Bragg reflector 122, which are disposed on opposite sides of the light-emitting structure 16 respectively, so as to allow light emitted from the light-emitting structure 16 to exit from either of the opposite sides.

A material of the first epitaxial sub-layer 131 and a material of the second epitaxial sub-layer 132 are the same and both may be GaN. The material of the active layer 14 may be at least one of AlGaN, InGaN, or AlInGaN. The material of the second epitaxial layer 15 may be GaN. The conductive type of the second epitaxial sub-layer 132 is opposite to that of the second epitaxial layer 15, for example, and one is P-type doped and the other is N-type doped.

Referring to FIG. 9(a), the first Bragg reflector 121 may be located on the light-emitting structure 16 and on the second mask layer 12, and the second Bragg reflector 122 is located on a side of the base 10 away from the first mask layer 11. Referring to FIG. 9(b), the light-emitting structure 16 does not fill up the second channel 120, the first Bragg reflector 121 is located on the light-emitting structure 16, and the first Bragg reflector 121 is located within the second channel 120.

The first Bragg reflector 121 and the second Bragg reflector 122 both include a plurality of repeating units, and each of the plurality of repeating units may include two layers of materials with different refractive indices. When a number of repeating units of the first Bragg reflector 121 is smaller than that of the second Bragg reflector 122, the first Bragg reflector 121 corresponds to a light-emitting surface of the light-emitting structure 16; when the number of repeating units of the first Bragg reflector 121 is larger than that of the second Bragg reflector 122, the second Bragg reflector 122 corresponds to the light-emitting surface of the light-emitting structure 16.

When the second channel 120 is plural in number, each second channel 120 has a different size, and the spaced second channels 120 may have different spacing distances, to obtain the laser diode 7 with different light-emitting wavelengths.

For example, a smaller cross sectional area of the second channel 120 means a smaller proportion of the cross sectional area of the second channel 120 per unit area, i.e., a smaller hole percentage of the second channel 120, the smaller the hole percentage of the second channel 120 is, the faster the growth rate of the base material (GaN) of the active layer 14 within the second channel 120 is, and the doping of In element has better selectivity, thereby the doping rate of In element is greater than the doping rate of Ga element. Therefore, the smaller the hole share of the second channel 120 is, the higher the component content of In element in the active layer 14 (InGaN) is, the longer the light-emitting wavelength of the light-emitting structure 16 is. The larger the cross sectional area of the second channel 120 is, the lower the component content of In element in the active layer 14 (InGaN) is, the shorter the light-emitting wavelength of the light-emitting structure 16 is.

The larger spacing distance between adjacent second channels 120 means a smaller proportion of the cross sectional area of the second channel 120 per unit area, i.e., a smaller hole percentage of the second channel 120, the higher the component content of In element in the active layer 14 (InGaN) is, the longer the light-emitting wavelength of the light-emitting structure 16 is. The smaller the spacing distance between adjacent second channels 120 is, the lower the component content of In element in the active layer 14 (InGaN) is, and the shorter the light-emitting wavelength of the light-emitting structure 16 is.

In other embodiments, when the light-emitting structure 16 does not fill up the second channel 120, a partial number of repeating units of the first Bragg reflector 121 may be located within the second channel 120, and another partial number of repeating units are located outside the second channel 120; or the light-emitting structure 16 fully fills the second channel 120 and the first Bragg reflector 121 is epitaxially grown on the light-emitting structure 16.

FIG. 10 is a flowchart illustrating a method for manufacturing a laser diode according to a seventh embodiment of the present disclosure. Referring to FIG. 10, the method for manufacturing the laser diode 7 of this seventh embodiment includes the following steps S21 to S23.

At step S21, any one of the structures 1, 2, 3, 4, 5, and 6 of the first to sixth embodiments is provided.

At step S22, a first epitaxial layer 13, an active layer 14 and a second epitaxial layer 15 are formed sequentially by performing an epitaxial growth process on the base 10 with the first mask layer 11 and the second mask layer 12 as masks, where the first epitaxial layer 13 includes a first epitaxial sub-layer 131 and a second epitaxial sub-layer 132, the first epitaxial sub-layer 131 is epitaxially grown from the base 10 to fully fill the first channel 110, the second epitaxial sub-layer 132 is epitaxially grown, from the first epitaxial sub-layer 131 located at the first open end 110a, in the second channel 120, the active layer 14 is located within the second channel 120, and a light-emitting structure 16 is formed by the second epitaxial sub-layer 132, the active layer 14 and the second epitaxial layer 15.

At step S23, a first Bragg reflector 121 and a second Bragg reflector 122 which are disposed on opposite sides of the light-emitting structure 16 are respectively formed, so as to allow light emitted from the light-emitting structure 16 to exit from either of the opposite sides.

In step S22, the process for forming the first epitaxial sub-layer 131, the second epitaxial sub-layer 132, the active layer 14, and the second epitaxial layer 15 may include: atomic layer deposition (ALD), or chemical vapor deposition (CVD), or molecular beam epitaxy (MBE), or plasma enhanced chemical vapor deposition (PECVD), or low pressure chemical vapor deposition (LPCVD), or metal-organic chemical vapor deposition (MOCVD), or a combination thereof. The dopant ions in the second epitaxial sub-layer 132 and in the second epitaxial layer 15 may be doped in-situ.

When the base 10 is a multilayer structure, for example, the base 10 includes a semiconductor substrate 100 and a nucleation layer disposed on the semiconductor substrate 100, the first epitaxial sub-layer 131 and the second epitaxial sub-layer 132 are heterogeneous epitaxial layers. When the base 10 is a single-layer structure, for example, the base 10 is a silicon carbide semiconductor substrate 100, the first epitaxial sub-layer 131 and the second epitaxial sub-layer 132 are homogeneous epitaxial layers.

A material of the first epitaxial sub-layer 131 and a material of the second epitaxial sub-layer 132 are the same and both may be GaN-based material. The dislocation in the GaN-based material is along a thickness direction of the first mask layer 11 or have an angle to the thickness direction. The fact that the area of the orthographic projection of the first open end 110a of the first channel 110 in the plane where the base 10 is located is smaller than the area of the orthographic projection of the first channel 110 in the plane where the base 10 is located means that in the direction from the second open end 110b towards the first open end 110a, the first channel 110 has an inwardly converging sidewall, such that the dislocation of the epitaxially grown GaN-based material can terminate in the sidewall of the first channel 110 and cannot continue to extend in the second channel 120. Thus, the base 10 having the first mask layer 11 and the second mask layer 12 described above can reduce the dislocation density of the second epitaxial sub-layer 132. The active layer 14 and the second epitaxial layer 15 are formed by performing an epitaxial growth on the second epitaxial sub-layer 132, and thus, the dislocation density in the active layer 14 and in the second epitaxial layer 15 can also be reduced.

In step S23, for the laser diode 7 in FIG. 9(a), for the first Bragg reflector 121 and the second Bragg reflector 122, alternated layers of materials with different refractive indices can be formed by a deposition process. For the laser diode 7 in FIG. 9(b), the first Bragg reflector 121 may be formed by an epitaxial growth process, for example, the third sub-layer 114 and the fourth sub-layer 115 arranged alternately have materials of AlInN and GaN, or AlGaN and GaN, respectively. A partial number of repeating units of the third sub-layer 114 and the fourth sub-layer 115 may be located inside the second channel 120, and another partial number of repeating units of the third sub-layer 114 and the fourth sub-layer 115 are located outside the second channel 120, or the light-emitting structure 16 fully fills the second channel 120, and the third sub-layer 114 and the fourth sub-layer 115 are alternately grown on the light-emitting structure 16 by an epitaxial growth process. For the second Bragg reflector 122, alternated layers of materials with different refractive indices are formed by a deposition process.

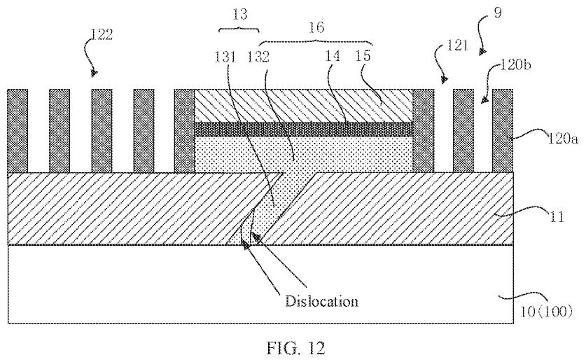

FIG. 11 is a schematic diagram illustrating a section of a laser diode according to an eighth embodiment of the present disclosure.

Referring to FIG. 11, the laser diode 8 and a method for manufacturing the same of the eighth embodiment differ from the laser diode 7 and the method for manufacturing the same of the seventh embodiment in that the first mask layer 11 includes a fifth sub-layer 116 and a sixth sub-layer 117 arranged alternately to correspondingly form the second Bragg reflector 122.

The fifth sub-layer 116 and the sixth sub-layer 117 have different refractive indices.

In addition to the above difference, other parts of the laser diode 8 and process steps of manufacturing the laser diode 8 in the eighth embodiment can be referred to the corresponding parts of the laser diode 7 and the process steps in the seventh embodiment.

FIG. 12 is a schematic diagram illustrating a section of a laser diode according to a ninth embodiment of the present disclosure.

Referring to FIG. 12, the laser diode 9 of the ninth embodiment differs from the laser diodes 7 and 8 of the seventh and eighth embodiments in that: the second mask layer 12 on opposite sides of the light-emitting structure 16 is a plurality of protruding walls 120a spaced in a direction perpendicular to an end face of the light-emitting structure 16 to correspondingly form the first Bragg reflector 121 and the second Bragg reflector 122, so as to allow the light emitted from the light-emitting structure 16 to exit from either of the opposite sides in the direction perpendicular to the end face of the light-emitting structure 16.

Specifically, the first Bragg reflector 121 and the second Bragg reflector 122 both include a plurality of repeating units, and each of the plurality of repeating units includes a protruding wall 120a and an air gap 120b adjacent a side of the protruding wall 120a. When a number of repeating units of the first Bragg reflector 121 is smaller than that of the second Bragg reflector 122, the first Bragg reflector 121 corresponds to a light-emitting surface of the light-emitting structure 16. When the number of repeating units of the first Bragg reflector 121 is larger than that of the second Bragg reflector 122, the second Bragg reflector 122 corresponds to the light-emitting surface of the light-emitting structure 16.

In this embodiment, the plurality of protruding walls 120a respectively have the same width, and air gaps 120b between the plurality of protruding walls (i.e., adjacent protruding walls) 120a respectively have the same width. In other embodiments, at least two protruding walls 120a have different widths, and air gaps 120b of at least two pairs of adjacent protruding walls 120a have different widths.

In addition to the above difference, other parts of the laser diode 9 and process steps of manufacturing the laser diode 9 in the ninth embodiment can be referred to the corresponding parts of the laser diodes 7 and 8, and the process steps in the seventh and eighth embodiments.

Accordingly, a method for manufacturing the laser diode 9 of the ninth embodiment differs from the methods for manufacturing the laser diodes 7 and 8 of the seventh and eighth embodiments in that: in step S23, the second mask layer 12 on opposite sides of the light-emitting structure 16 is etched to form a plurality of protruding walls 120a spaced in the direction perpendicular to the end face of the light-emitting structure 16, to correspondingly form the first Bragg reflector 121 and the second Bragg reflector 122. The second mask layer 12 is made of a different material from the first mask layer 11, such that the first mask layer 11 can be used to detect the etching end.

In addition to the above difference, other steps of the method for manufacturing the laser diode 9 of the ninth embodiment can be referred to the corresponding steps of the method for manufacturing the laser diodes 7 and 8 of the seventh and eighth embodiments.

Compared to related arts, the present disclosure has the following beneficial effect.

The base having the first mask layer and the second mask layer is served as a base for epitaxially growing the GaN-based material, the area of the orthographic projection of the first open end of the first channel of the first mask layer in the plane where the substrate is located is smaller than the area of the orthographic projection of the first channel in the plane where the substrate is located, and the first channel has an inwardly converging sidewall, such that the dislocation of the epitaxially grown GaN-based material can terminate in the sidewall of the first channel and cannot continue to extend in the second channel 120. Thus, the base having the first mask layer and the second mask layer described above can reduce the dislocation density of the GaN-based material.

Although the present disclosure is disclosed as above, the present disclosure is not limited thereto. Any person skilled in the art may make various changes and modifications without departing from the spirit and scope of the present disclosure, and therefore the scope of protection of the present disclosure will be subject to the scope defined by the claims.

What is claimed is:

1. A structure, comprising:
a base;
a first mask layer on the base, wherein the first mask layer has a first channel exposing the base, the first channel comprises a first open end and a second open end, the second open end is close to a surface of the base, the first open end is away from the surface of the base, and an area of an orthographic projection of the first open end in a plane where the base is located is smaller than an area of an orthographic projection of the first channel in the plane; and
a second mask layer on the first mask layer, wherein the second mask layer has a second channel exposing the first mask layer, and the second channel is connected to the first channel.

2. The structure of claim 1, wherein the first mask layer is a multilayer structure, the first mask layer comprises a first sub-layer close to the base and a second sub-layer away from the base, and a material of the second sub-layer is different from that of the second mask layer.

3. The structure of claim 1, wherein the first mask layer and the second mask layer are both single-layer structures, and a material of the first mask layer is different from that of the second mask layer.

4. The structure of claim 1, wherein an area of a cross section of the second channel is larger than an area of the first open end of the first channel.

5. The structure of claim 1, wherein the orthographic projection of the first open end in the plane where the base is located does not overlap at least partially with the second open end.

6. The structure of claim 1, wherein the first channel is an inclined columnar channel.

7. The structure of claim 1, wherein
in an extending direction from the second open end towards the first open end, a cross sectional area of the first channel firstly increases and then decreases; or
in an extending direction from the second open end towards the first open end, a cross sectional area of the first channel gradually decreases; or
in an extending direction from the second open end towards the first open end, a cross sectional area of the first channel is constant.

8. The structure of claim 1, wherein a line connecting centres of cross sections of the first channel in an extending direction from the second open end towards the first open end is a straight line, a polyline, or a curve.

9. A laser diode, comprising:
the structure according to claim 1;
a first epitaxial layer comprising a first epitaxial sub-layer and a second epitaxial sub-layer, wherein the first epitaxial sub-layer is epitaxially grown from the base to fully fill the first channel, and the second epitaxial sub-layer is epitaxially grown, from the first epitaxial sub-layer located at the first open end, in the second channel;
an active layer on the second epitaxial sub-layer, wherein the active layer is located within the second channel;
a second epitaxial layer on the active layer, wherein a light-emitting structure is formed by the second epitaxial sub-layer, the active layer and the second epitaxial layer; and
a first Bragg reflector and a second Bragg reflector, which are on opposite sides of the light-emitting structure respectively, so as to allow light emitted from the light-emitting structure to exit from either of the opposite sides.

10. The laser diode of claim 9, wherein the second mask layer on the opposite sides of the light-emitting structure comprises a plurality of protruding walls spaced in a direction perpendicular to an end face of the light-emitting structure to correspondingly form the first Bragg reflector and the second Bragg reflector, so as to allow the light emitted from the light-emitting structure to exit from either of the opposite sides in the direction perpendicular to the end face of the light-emitting structure.

11. The laser diode of claim 10, wherein the first Bragg reflector and the second Bragg reflector both comprise a plurality of repeating units, and each of the plurality of repeating units comprises a protruding wall and an air gap adjacent a side of the protruding wall; when a number of repeating units of the first Bragg reflector is smaller than that of the second Bragg reflector, the first Bragg reflector corresponds to a light-emitting surface of the light-emitting structure; when the number of repeating units of the first Bragg reflector is larger than that of the second Bragg reflector, the second Bragg reflector corresponds to the light-emitting surface of the light-emitting structure.

12. The laser diode of claim 11, wherein the plurality of protruding walls respectively have the same width, and air gaps between the plurality of protruding walls respectively have the same width.

13. The laser diode of claim 9, wherein the first mask layer comprises a fifth sub-layer and a sixth sub-layer arranged alternately to form the second Bragg reflector, and the first Bragg reflector is on the light-emitting structure and on the second mask layer, or on the light-emitting structure within the second channel.

14. A method for manufacturing a structure, comprising:
providing a base;
forming a first mask layer on the base;
forming a first channel within the first mask layer that exposes the base, wherein the first channel comprises a first open end and a second open end, the second open end is close to a surface of the base, the first open end is away from the surface of the base, and an area of an orthographic projection of the first open end in a plane where the base is located is smaller than an area of an orthographic projection of the first channel in the plane;
forming a second mask layer on the first mask layer; and
forming a second channel within the second mask layer that exposes the first mask layer, wherein the second channel is connected to the first channel.

15. The method of claim 14, wherein the first mask layer is a multilayer structure, the first mask layer comprises a first sub-layer close to the base and a second sub-layer away from the base, and a material of the second sub-layer is different from that of the second mask layer.

16. A method according to claim 14, wherein the first mask layer and the second mask layer are both single-layer structures, and a material of the first mask layer is different from that of the second mask layer.

17. A method for manufacturing a laser diode, comprising:
providing the structure according to claim 1;
forming a first epitaxial layer, an active layer and a second epitaxial layer sequentially by performing an epitaxial growth process on the base with the first mask layer and the second mask layer as masks, wherein the first epitaxial layer comprises a first epitaxial sub-layer and a second epitaxial sub-layer, the first epitaxial sub-layer is epitaxially grown from the base to fully fill the first channel, the second epitaxial sub-layer is epitaxially grown, from the first epitaxial sub-layer located at the first open end, in the second channel, the active layer is located within the second channel, and a light-emitting structure is formed by the second epitaxial sub-layer, the active layer and the second epitaxial layer; and
forming a first Bragg reflector and a second Bragg reflector disposed on opposite sides of the light-emitting structure respectively, so as to allow light emitted from the light-emitting structure to exit from either of the opposite sides.

18. The method of claim 17, wherein forming the first Bragg reflector and the second Bragg reflector comprises:
etching the second mask layer on the opposite sides of the light-emitting structure to form a plurality of protruding walls spaced in a direction perpendicular to an end face of the light-emitting structure to correspondingly form the first Bragg reflector and the second Bragg reflector, so as to allow the light emitted from the light-emitting structure to exit from either of the opposite sides in the direction perpendicular to the end face of the light-emitting structure.

19. The method of claim 18, wherein the plurality of protruding walls respectively have the same width, and air gaps between the plurality of protruding walls respectively have the same width; the first Bragg reflector and the second Bragg reflector both comprise a plurality of repeating units, and each of the plurality of repeating units comprises a protruding wall and an air gap adjacent a side of the protruding wall; when a number of repeating units of the first Bragg reflector is smaller than that of the second Bragg reflector, the first Bragg reflector corresponds to a light-emitting surface of the light-emitting structure; when the number of repeating units of the first Bragg reflector is larger than that of the second Bragg reflector, the second Bragg reflector corresponds to the light-emitting surface of the light-emitting structure.

20. The method of claim 17, wherein the base is a single-layer structure, the first epitaxial layer is formed by performing a homogeneous epitaxial growth process or a heterogeneous epitaxial growth process on the base; or the base comprises a semiconductor substrate and a transition layer disposed on the semiconductor substrate, and the first epitaxial layer is formed by performing a homogeneous epitaxial growth process or a heterogeneous epitaxial growth process on the transition layer.
